(19) United States
(12) Patent Application Publication
(10) Pub. No.: US 2004/0211661 A1
(43) Pub. Date: Oct. 28, 2004

(54) Method for plasma deposition of a substrate barrier layer

(76) Inventors: Da Zhang, Austin, TX (US); Dean J. Denning, Del Valle, TX (US); Peter L. G. Ventzek, Austin, TX (US)

Correspondence Address: FREESCALE SEMICONDUCTOR, INC., LAW DEPARTMENT, 7700 WEST PARMER LANE MD:TX32/PL02, AUSTIN, TX, 78729, US

(21) Appl. No.: 10/421,224

(22) Filed: Apr. 23, 2003

(51) Int. Cl. C23C 14/32

(52) U.S. Cl. 204/192.12; 204/192.17; 204/192.3

(57) ABSTRACT

A method for depositing a barrier or coating layer (34) in a semiconductor recessed structure (28) within a substrate (20) using a plasma process (62) that includes alternating depositing steps (64) and resputtering steps (66). The depositing step (64) deposits a barrier layer (34), including a thick bottom region (38) and a sidewall region (40) along the recessed structure (28) surface. The resputtering step (66) reduces the barrier layer (34) thickness in the bottom region (38) and increases the barrier layer (34) thickness in the otherwise thinly covered portions of the substrate sidewall region (40). Control of powers ranges supplied to the sputtering target (14) and the substrate (20) achieve the depositing and resputtering steps. The process applies also to other coating layers than barrier layers (34), providing a uniform sidewall coverage and thin bottom coverage, e.g., for permalloy deposition in MRAM devices and dual gate electrode formation in CMOS devices.

### FIELD OF THE INVENTION

The present invention relates to semiconductor devices and, more particularly, to a method for depositing a barrier layer on a substrate.

### BACKGROUND OF THE INVENTION

Deposition of barrier or coating layers for copper interconnects occurs in integrated circuit manufacturing processes. These barrier layers surround copper layers within deep recessed features (e.g., trenches and substrate vias) of interconnect lines and prevent copper from diffusing to other regions of the semiconductor device. Typical barrier materials include tantalum, tantalum nitride, titanium, titanium nitride, and the like. The electrical resistance of barrier materials is higher than that of copper, therefore it is necessary to avoid excessive usage of barrier material to ensure low electrical resistance for the interconnect line.

High power magnetron-enhanced physical vapor deposition (PVD) systems are examples of equipment useful for semiconductor device barrier layer deposition processes. Characteristics of state-of-the-art fabrication systems for forming such barrier layers include a process chamber with a relatively large space between the target and substrate, as well as the use of magnetron for plasma environment enhancement. In such systems, a DC power source connects to a sputtering target. Coupled with magnetron enhancement, the DC power enables ionization of a supplied source gas, such as argon gas, and creates plasma in the process chamber. The DC power produces plasma ions that strike the target with high energy, resulting in sputtering of the target and ejection of target material into the plasma environment. The sputtered target particles then transport to the substrate. This results in their deposition in substrate recessed structures such as vias. In these types of fabrication systems, there is also typically an electrical connection to the wafer substrate to provide an RF bias power to the substrate.

To ensure uniform deposition on recessed feature surfaces, these types of fabrication systems typically operate at high target powers (approximately 24 KW) and low pressures (approximately 2 mTorr). The applicable RF bias power is much lower than the target power, due to other concerns such as wafer heating. In fact the RF bias power typically is less than 1000 W. In this fabrication environment, a majority of the sputtered species from the target migrate to the wafer without many collisions with the background gas. Since few collisions occur, this process preserves the initial directionality of the sputtered target particles.

While a deposition flux having the original directionality property favors the formation of acceptable sidewall coverage for the barrier layer, a drawback of these conventional barrier PVD processes is that they typically form very thick bottom coverage at the recessed region of the substrate. The thick bottom coverage arises from the center-focused angle distribution of deposition flux, which includes neutrals and ions.

Unfortunately, thick barrier layer bottom regions generally produce contact substrate vias demonstrating undesirably high substrate via resistances. High substrate via resistances lead to high RC time constants, which lead to undesirable circuit signal delays. This makes semiconductor devices having such substrate vias less useful for high performance integrated circuit applications than devices having lower resistance substrate vias. Some approaches to solving the thick barrier layer bottom coverage problem seek to resputter the deposited materials using an RF bias of some sort at the substrate. However, wafer resputtering with RF bias has not heretofore proven successful

Moreover, in many of these barrier layer deposition processes, the deposited barrier layer at the lower portion of the feature sidewall region generally becomes much thinner than, not only the thicker bottom region, but also the upper sidewall region of the recess where there may be a thick overhang coverage or barrier material. This poses the risk of insufficient barrier at the lower sidewall region for preventing copper diffusion. The imbalance of a thick bottom region, a thin lower sidewall region, and thicker overhang coverage degrades the resulting semiconductor device's performance.

The barrier layers formed from known operations of high power PVD systems also create mechanical stresses in the resulting semiconductor devices. The lack of uniformity that these barrier layers demonstrate—a thick bottom and overhang coverage together with a thinner lower sidewall region—gives rise to differing local regions of greater and lesser material strength properties. These variances challenge the durability and performance of the resulting integrated circuit when mechanical and thermal variances occur, not only during their fabrication, but also during their subsequent operation.

One approach to addressing these problems involves an RF power supply that connects to an inductive coil. The inductive coil generates a high density plasma in the region between the target and the substrate. While such RF coil systems may address the problems of a non-uniform barrier layer, they also have limitations. Such limitations include the inherent costs of installing such systems in existing PVD equipment or the additional cost of manufacturing or purchasing new PVD equipment which includes these types of additional RF coil systems. Also, it should be expected that these RF coil systems may cause variances in PVD processes compared to other systems not similarly equipped.

### BRIEF DESCRIPTION OF THE DRAWINGS

The following drawings illustrate a semiconductor device barrier or coating layer plasma deposition method and a recessed structure resulting there from which are to be viewed in conjunction with a reading of the following Detailed Description, and wherein:

FIG. 1 is a diagrammatic view of a semiconductor device fabrication process chamber for implementing the present invention;

FIG. 2 presents the concept of forming a semiconductor device substrate via including a barrier layer;

FIG. 3 depicts a thick barrier layer bottom layer region, which problem the present invention solves;

FIG. 4 shows the problem of a thin barrier layer lower sidewall region and thick overhang coverage, which the present invention remedies;

FIGS. 5 and 6 illustrate the process for depositing and resputtering the barrier layer according to the teachings of the present invention;

FIG. 7 provides a measure of the ion flux available in the low target power region as a function of increasing substrate RF bias voltage; and

FIG. 8 illustrates basic steps for achieving barrier layer deposition-resputtering process according to the present invention.

### DETAILED DESCRIPTION

Generally, the present invention provides a method for depositing a barrier or coating on a substrate which process results in thinner bottom coverage, improved sidewall coverage, to yield an overall improvement in device performance. One aspect of the present invention is a two-step pulsed process involving control of power sources that connects to a sputtering target and the substrate, as well as control of the process pressure within a fabrication chamber. The present invention employs control of plasma deposition in a low power regime of sputtering target power supply operation to reduce substrate via resistance.

The pulsed-mode process of the present invention includes a barrier layer PVD deposition step followed by localized barrier layer in situ resputtering at the substrate. In the deposition step, the present invention employs typical PVD operating conditions of a high target power, a low/no substrate RF bias at the substrate, and a low processing pressure within the plasma processing environment. In a subsequent substrate resputtering step, the plasma target power switches to an unusually low value (on the order of ˜1 KW) for plasma processing. Also, during this resputtering step, the substrate RF bias power may present to the substrate a higher than otherwise normal power level.

In conventional PVD processes, a high target power produces a high ion current to the substrate. Because the bias power is approximately determined by the product of ion current and sheath voltage at the substrate, the high current swamps the sheath voltage at the substrate. This leads to very low ion energy that is insufficient for effective substrate via resputtering. Therefore, the conventional approach cannot mitigate the intrinsic thick bottom coverage problem. Moreover, in the conventional processes the deposited barrier layer at the lower portion of the feature sidewall region oftentimes becomes, not only much thinner than the thicker bottom region, but also thinner than the upper sidewall region of the substrate via, where there may be a thick overhang coverage. This poses the risk of insufficient barrier coverage at the lower sidewall region for preventing copper diffusion. The imbalance of a thick bottom region, a thin lower sidewall region, and thicker overhang coverage degrades the resulting semiconductor device's performance.

The deposition/resputtering pulsed mode operation of the present invention, to the contrary, optimizes barrier layer coverage on both the barrier layer bottom layer and sidewalls. A significant aspect of the present invention, therefore, includes providing in the resputtering mode a low, but not zero, target power for producing only a small local ion flux at the substrate. The high RF bias power which the process applies to the substrate itself induces a high energy relative to the sputter threshold energy for ions striking the substrate. This novel combination enables efficient ion sputtering at the substrate via bottom, i.e., to achieve a reduction in the barrier bottom layer thickness.

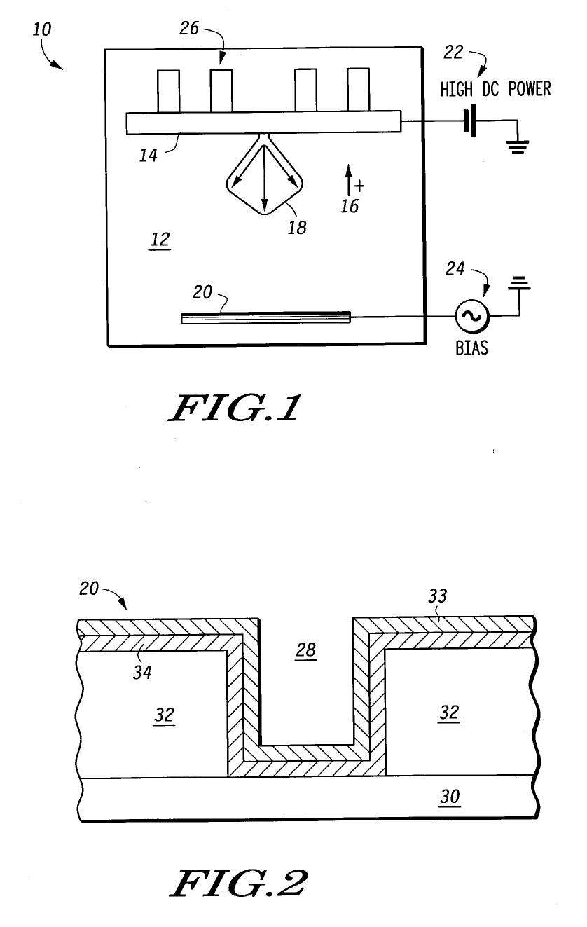

These and other features and advantages of the present invention will become more clearly understood from the remaining portion of this Detailed Description which is to taken in conjunction with FIGS. 1 through 8. It is important to point out, however, that the illustrations are not necessarily drawn to scale, and that there are likely to be other embodiments of the present invention which are not specifically illustrated. Furthermore, it is important to note that like reference numerals are sometimes used throughout the several figures to designate identical or corresponding parts.

One embodiment of the plasma process of the present invention involves a sequence of alternating depositing and resputtering steps. Such a sequence may occur in rapid succession or more slowly, depending on considerations such as the use of different process parameters and barrier materials. A depositing step deposits a barrier layer into the substrate via. The barrier layer has a bottom region and a side region. The resputtering step includes resputtering the barrier layer for reducing the barrier layer thickness in the bottom region. During the resputtering process, the sidewall barrier layer thickness increases and, thereby, is made more homogenous relative to the initial thickness distribution. The redistribution of the already-deposited barrier layer improves or reduces the overall substrate via resistance. A high degree of barrier layer thickness uniformity also reduces localized mechanical stresses in the barrier layer. The result is a more reliable and resilient barrier layer.

Depositing the barrier or coating layer, in the present process, may involve the use of a high target power and a low RF bias power to the substrate. For example, during barrier layer deposition, the high deposition target power may exceed 12 KW, and preferably range between 18 and 48 KW, while the low deposition RF bias power may be lower than 300 W, and may be approximately 0 W. With this configuration, deposition occurs at a high rate.

During resputtering, the target power is significantly lower than the target power used during barrier layer deposition. The high resputtering RF bias power preferably greatly exceeds the low deposition RF bias power. For example, the low resputtering target power may be lower than 6 KW, and preferably between 0.5 KW and 2 KW, while the high resputtering RF bias power may exceed 500 W, and preferably range between 600 W and 1000 W.

To illustrate one embodiment of the present invention, refer to FIG. 1, which shows diagrammatically a fabrication process chamber 10 for establishing plasma processing environment 12. In plasma processing environment 12 appears sputtering target 14. Sputtering target 14 is bombarded by accelerated plasma ions 16 which dislodge and eject target material 18 from sputtering target 14. Target material 18 then deposits onto substrate 20, which may be a semiconductor wafer. Plasma processing environment 12 may be maintained, for example, at a pressure of between 2 and 15 milliTorr. Typically, a heavy inert gas such as argon is supplied to the plasma processing environment 12 and a pumping system maintains the desired gas pressure in fabrication process chamber 10. A glow discharge plasma is created in the low pressure argon, at least partially ionizing the gas, by supplying from target power source 22 a DC power to sputtering target 14. Magnetron 26 enhances or facilitates control of plasma ions 16 within plasma processing environment 12. Since plasma ions 16 provide a good conductor, plasma processing environment 12 remains at essentially a constant positive potential with respect to the grounded chamber wall. This produces an electric field at sputtering target 14 that is substantially perpendicular to the exposed surface of sputtering target 14. Thus, positive plasma ions 16 accelerate across plasma processing environment 12 and impact the exposed surface of sputtering target 14 following trajectories substantially perpendicular to the exposed front surface of sputtering target 14. This results in the sputtering of sputtering target 14. RF bias power 24 connects to wafer substrate 20. Ideally, RF bias power 24 provides high energy to ions incident to wafer substrate 20. Sputtered material 18 transports through low pressure plasma region 12 and deposits on the wafer substrate 20 surface.

The goal is to deposit films in recessed structures (trenches and vias) on the substrate 20 with thin coverage at the bottom of the structures and with good uniformity along structures' sidewall surface. The most widely used barrier materials include tantalum (Ta), tantalum nitride (TaN), tungsten (W), tungsten nitride (WN), titanium (Ti), and titanium nitride (TiN). In the case of metal deposition with one element (e.g., Ta), the target material is the same as the film material to be formed on the substrate. In the case of compound deposition (e.g., TaN), the target material is either the same as the film material to be formed or just the metal component. For example, for TaN barrier layer deposition, the target can be TaN, or it can be Ta, with a plasma gas source separately supplying nitrogen.

FIG. 2 illustrates a cross section of a substrate via 28, which may be a semiconductor feature constructed to connect a conductive layer or line, such as metal line 30, to another conductive layer or line (not illustrated) above the substrate via. In order to construct substrate via 28, dielectric 32 is deposited on top of metal line 30 using a chemical vapor deposition step. Dielectric 32 effectively isolates metal line 30 from other semiconductor features. Note that dielectric 32 may be deposited in a single step, or in a series of steps, and that dielectric 32 may comprise a single or multiple layer formation of a dielectric or insulative material.

Next, the physical boundaries of substrate via 28 are defined by photolithography and etch processes commonly employed by those skilled in the art. Frequently a sputter clean step is also performed to clean out the bottom of the substrate via to ensure better contact with metal line 30. Once the bottom of substrate via 28 has been cleaned out, a barrier layer 34 is deposited. Barrier layer 34 may be formed of any suitable conductive material or combination of conductive materials, and serves to prevent diffusion or migration of subsequently deposited metal, such as copper. Following the deposition of barrier 34, typical processing steps include deposition of copper seed layer 33, electroplating filling of copper in the via space, and chemical mechanical polishing (CMP).

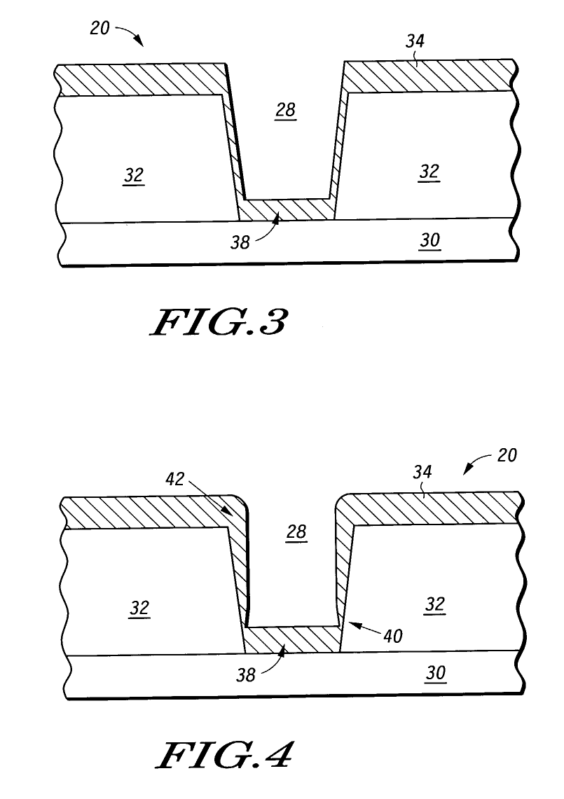

FIG. 3 illustrates barrier layer 34 having a nonoptimized thickness as thick bottom region 38 at the bottom of substrate via 28. Excessive thickness at bottom region 38 of substrate via 28 is undesirable because it can cause unacceptably high substrate via resistance. Although FIG. 3 shows relative uniformity along the sidewall regions, this may not occur in practice. For example, FIG. 4 shows a more likely occurrence, including thick overhang coverage 42. Thick overhang coverage 42 at the top of substrate via 28 is undesirable, because it can overshadow the inside of substrate via 28 and prevent proper deposition of metals on the bottom of the substrate via 28 sidewall region 40.

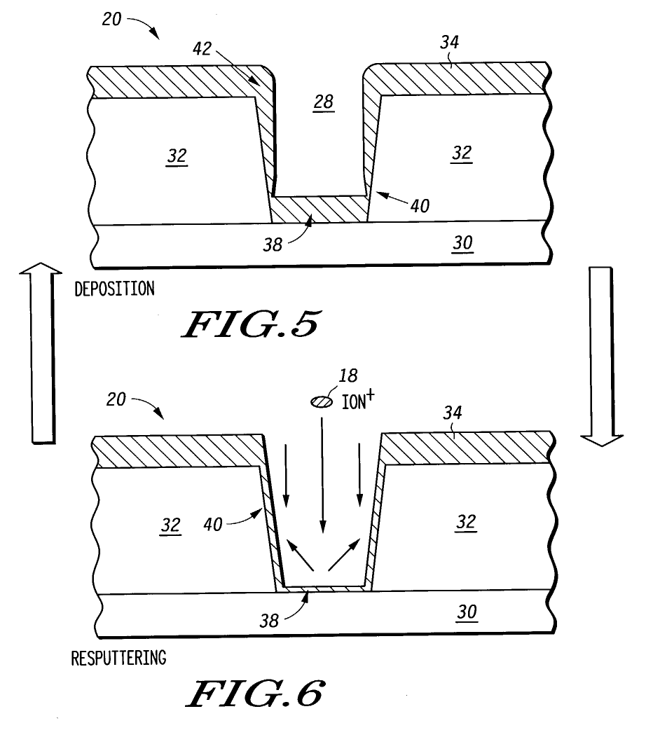

FIGS. 5 and 6 show the transformation that the resputtering steps of the present invention cause. FIG. 5 illustrates substrate via 28 resulting from a first step of high target power deposition. Referring to FIG. 5, there appears barrier or coating layer 34, which includes thick bottom region 38, thin sidewall region 40, and thick overhang coverage 42. FIG. 6 shows the effects of the resputtering step of the present process to cause redistribution of the deposited barrier layer 34. The resputtering process causes barrier layer material to move from thick bottom region 38 to increase the coverage of thinner sidewall region 40. Moreover, the excessive amount of barrier material in thick overhang coverage 42 also redistributes to increase the coverage thickness of sidewall region 40. The result appears in FIG. 6, in which thick bottom region 38 reduces in thickness and the upper sidewall region 40 loses thick overhang coverage 42. At the same time, the thickness of barrier material at lower sidewall region 40 increases. The result, which FIG. 6 depicts, is a more desirable structure for barrier layer 34.

In one embodiment of the present invention, multiple cycles of deposition and resputtering are performed, rather than performing a single resputtering step after an entire layer of the metal has been deposited. The deposition-resputtering cycle may be performed as many times as desired to achieve process objectives. It will also be appreciated that although the preceding discussion is based on the formation of a substrate via 28, other similar structures may be formed using the principles set forth herein.

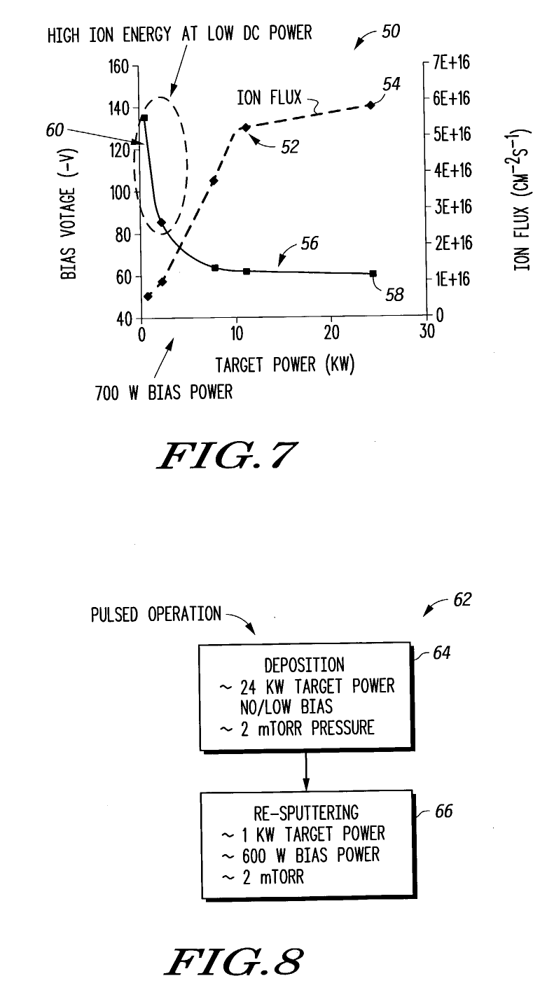

FIG. 7 shows diagram 50, which shows the ion flux values on ion flux line 52 and wafer bias voltage values on bias voltage line 56 with varying target power when the bias power was fixed at 700 W. Referring to FIG. 7, ion flux line 52 shows, at point 54 (target power of approximately 24 KW; ion flux of approximately 6×10¹⁶ cm⁻²s⁻¹), that the ion flux appears to be high at high target power values. Point 58 (target power approximate 24 KW; bias voltage approximately −60 volts) on bias voltage line 56 shows that substrate 20 bias voltage may be very low in magnitude at or near the sputtering threshold. In the low target power regime, represented by region 60 of bias line 56, a high ion energy is experienced for ions striking the wafer. This results from the reduced ion flux as shown in line 52. Region 60 describes a bias voltage ranging from approximately 85 V to approximately 135 V. This phenomenon shows that ion energy is significantly enhanced in the low target-power regime to enable wafer resputtering.

FIG. 8 shows a simplified process flow 62 for accomplishing one embodiment of the present invention. Referring to FIG. 8, in process flow 62 there appears the aspect of a deposition step 64 including first the deposition of barrier layer 34. This may occur, for example, using a 24 KW target power from target power source 22, either low or no substrate 20 bias power, and a low process pressure within plasma processing environment 12, such as a pressure of approximately 2 mTorr. Following deposition step 64, resputtering step 66 occurs. This may include the use of a target power from target power source 22 of approximately 1 KW and a substrate 20 bias power of approximately 600 W. The resputter step 66 can benefit from a slightly increased pressure, e.g., 15 mTorr. This is because increasing pressure further confines ions that may be away from substrate 20, thereby enhancing ion energy.

Process flow 62 conceptually depicts a sequence of an alternating deposition step 64 followed by resputtering step 66. These steps may occur in a pulsed mode in rapid succession. The result becomes a uniform and conformal barrier layer 34. Resputtering step 66, together with, or even separate and apart from, deposition step 64 is novel in that it effectively uses target power source 22 in a low power control regime for redistributing otherwise non-uniform regions of barrier layer 34. Moreover, the present invention makes possible the use of off-the-shelf power supplies to achieve a barrier layer 34 thickness distribution that is more uniform along the recessed structure surface, while effectively extending the usefulness of existing deposition equipment. The result is a significant savings in process equipment costs relative to other systems, such as those requiring the use of a separate RF inductive coil within the plasma processing environment. Moreover, with shrinking feature sizes, the use and value of the present process will continually increase, due to its providing a barrier layer 34 with more uniform thickness along the recessed structure surface and the resulting higher performance semiconductor device.

The improvement in barrier or coating layer 34 processing arising from the present invention can be dramatic. For example, the results of one use of the present invention were measured against a baseline deposition process wherein during barrier layer deposition a target power source supplied 18 KW to sputtering target 14 and no substrate 20 bias power was applied. In addition to the baseline deposition step 64, the example use included a pulsed or repetitious operation of process flow 62. This included a resputtering step 66 using a 500 W sputtering target power and a 500 W substrate 20 bias power. In this example, a 48% reduction in bottom layer coverage occurred coupled with an over 19% increase in sidewall coverage.

The process of the present invention also has valuable use in areas other than barrier or coating layer 34 deposition. For example, in the fabrication of magnetoresistive random access memory (MRAM) devices, a deposition of permalloy material is needed. The permalloy deposition can also be achieved by using the current invention. In the fabrication of a dual metal gate for CMOS devices (e.g., a FINFET), where a metal layer is deposited onto a island of silicon, the current invention can be applied to achieve the gate deposition. In general, this invention is useful for any situation that requires the deposition of a layer of material onto the surface of an un-flat structure and needs a conformal coverage on the vertical surface and a thin coverage on the horizontal surface of the structure.

Thus, it is apparent that there has been provided in accordance with the invention a method for depositing a barrier or coating layer in a plasma environment for semiconductor device fabrication and a structure resulting there from. The method includes a deposition and resputtering pulsed mode, or alternatively a non-pulsed mode, of operation for optimizing barrier layer coverage on both the bottom and sidewalls of recessed features in the substrate. Although the invention has been described and illustrated with reference to specific embodiments, it is not intended that the invention be limited to these illustrative embodiments. Those skilled in the art will recognize that modifications and variations can be made without departing from the spirit of the invention. For example, the invention is not limited to the particular size or dimensions illustrated. The present invention has use with any process involving the formation of a deposition layer on un-flat or recessed features, as well as with any deposition process where deposition may occur in the horizontal direction through a plasma-enhanced processing environment. Essentially any fabrication plasma process that achieves the same functions as described above will suffice for purposes of practicing the present invention. In addition, the invention is not limited to any particular type of integrated circuit described herein. Therefore, it is intended that this invention encompass all such modifications and variations which fall within the scope of the appended claims.

We claim:

1. A method for redistributing a coating layer in a substrate recessed structure during a fabrication process occurring within a fabrication process chamber, said fabrication process chamber comprising a plasma deposition sputtering target for receiving a target power, said coating layer comprising a thick coating layer coverage in a bottom region and a thin coating layer coverage in a side region, the method comprising the steps of:
applying a low resputtering target power to the plasma deposition sputtering target for inducing a resputtering plasma environment proximate the substrate, said low resputtering target power being significantly lower than a higher deposition target power applied to said plasma deposition sputtering target for initially depositing said coating layer and sufficiently high to cause localized ion flux near said substrate recessed structure; and
resputtering said coating layer within said resputtering plasma environment for reducing the coating layer thickness in the bottom region and increasing the coating layer thickness in the side region, thereby redistributing more uniformly said coating layer.

2. The method of claim 1, wherein said low resputtering target power is less than approximately 6 KW.

3. The method of claim 1, wherein said low resputtering target power ranges between approximately 0.5 KW and approximately 2 KW.

4. The method of claim 1, wherein the substrate receives an RF bias power of approximately 1 KW.

5. A method for depositing a coating layer into a substrate recessed structure within a semiconductor device during a fabrication process, comprising the steps of:
forming a coating layer in the substrate recessed structure using a plasma process, said plasma process comprising a sequence of an alternating depositing step and a resputtering step,
said depositing step comprising a step of depositing a coating layer into the substrate recessed structure for forming a coating layer along the substrate recessed structure, said coating layer having a bottom region and a side region; and
said resputtering step comprising a step of resputtering said coating layer for reducing the coating layer thickness in the bottom region using a low resputtering target power to the plasma deposition sputtering target for inducing a resputtering plasma environment proximate the substrate, said low resputtering target power being significantly lower than a higher deposition target power applied to said plasma deposition sputtering target during said depositing step and sufficiently high to cause localized ion flux near said substrate recessed structure.

6. The method of claim 5, wherein said resputtering step further increases coating layer thickness along a side region of said substrate recessed structure.

7. The method of claim 5, wherein said depositing step and said resputtering step operate in a pulsed mode in rapid succession during said coating layer forming step.

8. The method of claim 5, where said plasma process further comprises the steps of:
depositing said coating layer comprising the step of applying a high deposition DC power to a sputtering target and a low deposition RF bias power to the substrate; and
resputtering said coating layer using a low resputtering DC power to the sputtering target and a high resputtering RF bias power to the substrate, said low resputtering DC power being substantially lower than said high deposition DC power, and said high resputtering RF bias power being substantially greater than said low deposition RF bias power.

9. The method of claim 8, wherein said high deposition DC power exceeds approximately 12 KW.

10. The method of claim 8, wherein said high deposition DC power ranges from approximately 18 KW to approximately 48 KW.

11. The method of claim 8, wherein said low resputtering DC power approximates less than 6 KW.

12. The method of claim 8, wherein said low resputtering DC power ranges from approximately 0.5 KW to approximately 2 KW.

13. The method of claim 8, wherein said low deposition RF bias power approximates less than 300 W.

14. The method of claim 8, wherein said low deposition RF bias power approximates 0 W.

15. The method of claim 8, wherein said high resputtering RF bias power exceeds approximately 500 W.

16. The method of claim 8, wherein said high resputtering RF bias power ranges between approximately 600 W and approximately 1000 W.

17. The method of claim 5, wherein said coating layer comprises a diffusion barrier material.

18. The method of claim 5, wherein said coating layer comprises a permalloy material, and said semiconductor device is a magnetoresistive random access memory.

19. The method of claim 5, wherein said coating layer forms a gate electrode.
